(19) United States
(12) Patent Application Publication
(10) Pub. No.: US 2006/0267621 A1
(43) Pub. Date: Nov. 30, 2006

(54) On-chip apparatus and method for determining integrated circuit stress conditions

(76) Inventors: Edward B. Harris, Fogelsville, PA (US); Michael C. Ayukawa, Zionsville, PA (US); Philip W. Mason, Allentown, PA (US); Frank Yauchee Hui, Macungie, PA (US)

Correspondence Address: BEUSSE WOLTER SANKS MORA & MAIRE, P. A., 390 NORTH ORANGE AVENUE, SUITE 2500, ORLANDO, FL, 32801, US

(21) Appl. No.: 11/140,605

(22) Filed: May 27, 2005

(51) Int. Cl. G01R 31/26

(52) U.S. Cl. 324/765

(57) ABSTRACT

A method and apparatus for determining whether an integrated circuit has been subjected to stress conditions during operation. The integrated circuit comprises a test device that is exposed to the same power supply voltage and temperature as other devices in the integrated circuit. Certain expected operating parameters, as a function of the operating life of the integrated circuit, are predetermined. If a measured value of the operating parameter exceeds the expected value then the integrated circuit has been subjected to stress conditions.

### FIELD OF THE INVENTION

This invention relates generally to semiconductor integrated circuits, and more particularly to an apparatus and method for monitoring one or both of an integrated circuit temperature and a power supply voltage supplied to the integrated circuit.

### BACKGROUND OF THE INVENTION

Integrated circuits (or chips) typically comprise a silicon substrate with semiconductor devices, such as transistors, formed from doped regions within the substrate. Interconnect structures, also referred to as metallization layers, comprising substantially parallel conductive layers connected by substantially vertical conductive vias, provide electrical connection between doped regions to form electrical circuits within the integrated circuit. Typically several metallization layers are required to interconnect the doped regions in the integrated circuit. The top metallization layer provides attachment sites for receiving conductive interconnects (e.g., bond wires) that connect the integrated circuit to terminals (e.g., pins or leads) of a chip package structure, which further connect the integrated circuit to off-chip electronic components.

Integrated circuits are designed to operate at a nominal power supply voltage and within predetermined temperature limits. However, it is known that the integrated circuit can likely be safely and reliably operated within a supply voltage tolerance range above and below the nominal voltage and within a temperature tolerance range above and below the nominal temperature. Power supply voltage and/or temperature excursions outside design limits can cause immediate failure or reduce integrated circuit life. It is generally known that design or process modifications can be implemented to extend the supply voltage and temperature tolerance, thereby increasing the reliability margin of the integrated circuit, but at the expense of increased fabrication costs.

The expected lifetime of an integrated circuit is influenced by the voltage and temperature at which it is operated, in addition to the effects of anomalies that may occur during the fabrication process. To estimate the expected lifetime, a reliability failure analyses is performed by subjecting the fabricated chip to accelerated life testing, also referred to as stress testing. The reliability failure analysis is based on a worst-case operating scenario, considering the manufacturing processes employed to fabricate the chip and the chip's operational environment and anticipated use pattern, the latter including out-of-tolerance voltage and temperature conditions to which the chip might be subjected. By extrapolation from the chip performance data collected during these tests, the expected lifetime under normal operating conditions can be determined. Expected aging effects as a function of the chip's operating life, assuming the integrated circuit is operated within design limits, can also be determined. For example, an integrated circuit fabricated according to a specific technology may be rated at an operating voltage of 1.2 volts and have a ten year expected lifetime according to the accelerated life tests. It can also be determined from the accelerated tests that operating the chip at five volts reduces it lifetime to a nominal five years. Thus this chip would be expected to operate successfully at five volts in a system having a five year life or at 1.2 volts in a system having a ten year life.

Changes in manufacturing processes and the continual progression to smaller and denser devices may contribute to an erosion of the reliability margin, resulting in increased risk of premature chip failure. As semiconductor integrated circuits are scaled to smaller dimensions, the requirement to maintain operation within the power supply voltage and temperature limits becomes more critical. For instance, for integrated circuits comprising metal-oxide semiconductor field effect transistors (MOSFET's) with gate oxides having a thickness of less than about 2.5 nm, subjecting the integrated circuit to a power supply voltage of about 5% over the nominal voltage can reduce the expected mean lifetime from about ten years to about six years. If typical temperature specification limits (e.g., 90° to 125° C.) are exceeded, the chip lifetime can also be reduced.

Failure of an integrated circuit embedded within a system will likely cause a failure of the system, an unfortunate outcome that can be expensive and disruptive to the system user. For example, failure of a disk drive requires purchase of a replacement drive and entails a data recovery cost. Consequential losses such as data recovery can be costly and can easily exceed the hardware replacement cost. System redundancy is commonly employed to avoid the effects of component faults or defects that lead to a system failure. However, redundant systems incur an extra cost, i.e., a doubled cost.

Generally, when an integrated circuit fails in the field and is returned to the supplier for a failure analysis, it is difficult for the chip supplier to determine the failure's root cause, especially since the supplier lacks knowledge of voltage or temperature stresses or other operational abuses to which the integrated circuit may have been exposed during operation. This type of information, if available, could be invaluable to the supplier during a post-failure analysis.

In addition to after-the-fact failure analysis, a warning of a possible integrated circuit failure can be valuable to the end user, providing an opportunity to avoid or minimize consequential losses. Given the widespread use of integrated circuits in hardware devices, including life saving devices (e.g., biomedical implants) and mission critical devices (telecommunications devices and financial transaction devices), a warning of an impending failure allows the user to replace the hardware device and avoid a costly breakdown. Even when used in commonplace personal computers and appliances, a warning can prevent an annoying failure and the consequences thereof Unlike mechanical systems that generally provide a failure warning (e.g., excessive or unusual noise emanating from the system), electronic systems provide virtly no warning prior to a complete failure. Thus, the ability to warn the user that a failure might occur in the near term can be particularly advantageous.

### BRIEF SUMMARY OF THE INVENTION

According to one embodiment, the present invention comprises a method for determining exposure of an integrated circuit to operational stresses, wherein the integrated circuit comprises a test device and a reference device, and wherein the integrated circuit is connected to a power supply and to ground. The method comprises determining an operating parameter of the test device, determining the operating parameter of the reference device and determining an operating parameter shift in response to the operating parameter of the test device and the operating parameter of the reference device.

The invention further comprises an apparatus for determining exposure of an integrated circuit to operational stresses, wherein the integrated circuit is connected to a power supply and to ground. The apparatus comprises a test device formed in the integrated circuit, a reference device formed in the integrated circuit, a tester for determining an operating parameter of the test device and of the reference device and for determining an operating parameter shift in response to the operating parameter of the test device and the operating parameter of the reference device.

### BRIEF DESCRIPTION OF THE DRAWINGS

The foregoing and other features of the present invention will be apparent from the following more particular description of the invention as illustrated in the accompanying drawings, in which like reference characters refer to the same parts throughout the different figures. The drawings are not necessarily to scale, emphasis instead being placed upon illustrating the principles of the invention.

FIGS. 1 and 2 are schematic diagrams of an integrated circuit including an apparatus for determining overstress conditions according to the teachings of a first embodiment of the present invention.

FIGS. 3 and 4 are schematic diagrams of an integrated circuit including an apparatus for determining overstress conditions according to the teachings of a second embodiment of the present invention.

FIG. 5 is a flow chart setting forth method steps for determining overstress conditions according to the teachings of the present invention.

### DETAILED DESCRIPTION OF THE INVENTION

Before describing in detail the particular on-chip power supply and temperature monitoring process and apparatus according to the present invention, it should be observed that the present invention resides in a novel and non-obvious combination of hardware elements and process steps. Accordingly, these elements have been represented by conventional elements in the drawings and specification, wherein elements and process steps conventionally known in the art are described in lesser detail, and elements and steps pertinent to understanding the invention are described with greater detail.

As is known, exposure of an integrated circuit or components thereof, to an excessive power supply voltage and/or an excessive operating temperature may cause device failure or reduce the device's operating life due to premature aging. One specific observable effect of these stressed operating conditions is a threshold voltage shift in the MOSFETS of the integrated circuit.

An excessive operating temperature alone does not typically induce a stress condition on the integrated circuit, and thus does not lead to aging effects, such as a threshold voltage shift. However, when the integrated circuit is subjected to a temperature in excess of its temperature limit while a voltage is applied, a stress condition is induced and a threshold voltage shift may result.

Since the threshold voltage shift as a function of device age is determined during the accelerated life testing described above, an expected shift (when operated within design limits) as a function of operating life (i.e., the total operating time of the integrated circuit) is known. Comparison of the expected shift with the actual shift provides an indication of the stresses to which the integrated circuit had been subjected.

Generally, the threshold voltage shifts upwardly as a function of the device's age. Disadvantageously, at a higher threshold voltage the MOSFET switching speed is reduced. For example, assume that a 5% MOSFET threshold voltage shift is expected after 12 years of operational life when the device is operated within given design limits. If an integrated circuit fails after six years of operation, and it is determined that the MOSFET threshold voltage shifted by 10%, then likely the premature failure was caused by subjecting the chip to a supply voltage concurrently with an excess temperature (i.e., a temperature beyond the design limits) and/or to a supply voltage beyond design limits. If the actual threshold voltage shift for the MOSFETS on a chip can be determined, reference to the expected functional relationship between the threshold voltage shift and the operating life indicates the degree to which the integrated circuit was stressed during operation.

One embodiment of the present invention teaches fabricating an n-type metal-oxide semiconductor field effect transistor (NMOSFET) test device and an NMOSFET reference device in an integrated circuit. In lieu of the NMOSFET devices, or in addition thereto, a p-type metal-oxide field effect transistor (PMOSFEF) test device and a PMOSFET reference device can be fabricated in the integrated circuit. The NMOSFET or PMOSFET test device (or both the PMOSFET test device and the NMOSFET test device in an integrated circuit comprising both) is connected across the chip's power supply terminals (i.e., between a power supply voltage and ground) or across a supply voltage for a chip sub-circuit, and is thus subjected to the same power supply voltage (or a scaled voltage related thereto) and temperatures as the other operative devices in the integrated circuit or the sub-circuit.

The reference device is fabricated in an open-circuit configuration and remains in that condition during chip operation. Since no voltage is supplied to the reference device, it remains in an unstressed condition during operation and therefore would not be expected to undergo a threshold voltage shift.

According to one embodiment of the present invention, when a failed chip is returned to the supplier for a failure mode analysis, the threshold voltage of the NMOSFET test device and/or the PMOSFET test device within the chip is measured and compared with the threshold voltage of the respective NMOSFET/PMOSFET reference device. Comparison of the two threshold voltages tends to minimize or eliminate the influence of the fabrication process on the threshold voltage shift, since both the test MOSFETS and the reference MOSFETS were subjected to the same processing steps.

Once the threshold voltage shift is determined, aging effect curves are consulted to determine whether the failed chip exhibited a threshold voltage shift consistent with the number of months/years that it was in service, i.e., its operating life. If it is determined that the aging effects are beyond what was expected, then likely the chip was subjected to excessive power supply voltages or temperatures during operation, as such conditions can cause the observed accelerated aging effects. Thus the threshold voltage shift provides an indication of an integrated history of power supply stresses and temperature stresses experienced by the integrated circuit or the sub-circuit. By integrated history it is meant that details of the individual power supply and temperature stresses may not be known or determinable, but the cumulative affect of these stresses is manifested by the threshold voltage shift.

The integrated stresses can be deduced from one or both of two aging effect curves that relate the threshold voltage shift to the device's operating life. A threshold voltage shift in an NMOSFET device is typically caused by the trapping of hot carriers in the gate oxide. Thus the integrated history of power supply and temperature stresses experienced by the NMOSFET can be deduced from a hot carrier aging (HCA) effect curve that relates the hot carrier aging effect and the associated operating lifetime, to a threshold voltage change.

The PMOSFET test device threshold voltage shift can be associated with negative bias temperature instability (NBTI). The integrated history of power supply and temperature stresses can be deduced from an NBn aging effect curve that relates NBTI aging to a threshold voltage shift. It is generally known in the art that NBTI effects are more sensitive to temperature stresses and HCA effects are more sensitive to voltage stresses.

Using the HCA and NBTI aging effects to determine whether the MOSFET, and thus the integrated circuit, was subjected to temperature and/or voltage stresses, provides a more accurate failure diagnosis than prior art diagnoses and reduces the cost of post-failure analysis. As is known in the art, the hot carrier and NBTI aging effect curves can be derived during process technology qualification of the integrated circuit fabrication process, for later use according to the present invention for analysis of a failed chip.

It is known that MOSFET operating parameters, other than the threshold voltage, can change when the device is exposed to excess power supply voltages and/or operating temperatures. Thus according to another embodiment of the present invention, one or more of these parameters (e.g., “on” current, i.e., current flow through the MOSFET channel when in the “on” state, also referred to as the saturation current) can be used to determine the integrated history of stresses experienced by the integrated circuit. Thus a determination of the “on” current of a failed chip and comparison with the expected “on” current given the chip's operating lifetime, can provide an integrated history of power supply and temperature stresses.

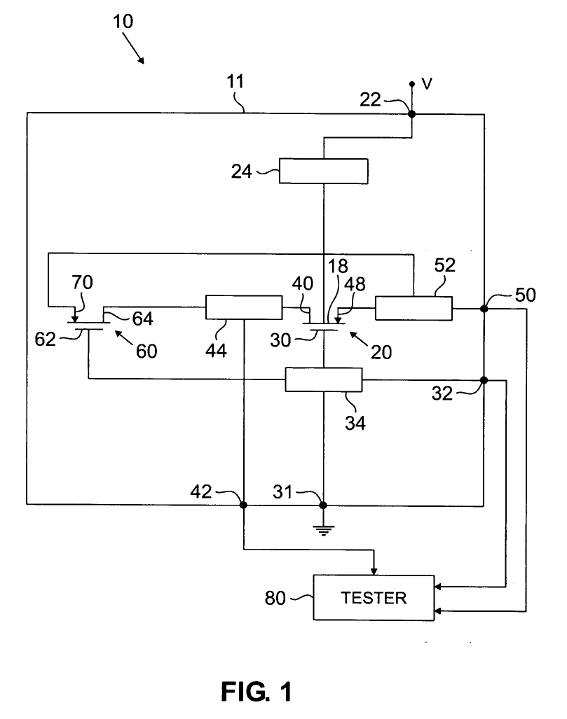

FIG. 1 illustrates an integrated circuit 10 comprising a plurality of active devices shown generally by a reference character 11. According to the teachings of the present invention, measurement of a stress-induced threshold voltage shift of a test device on the integrated circuit 10 is used to determine the integrated NBTI and HCA aging effects, from which voltage and temperature stress exposure can be determined during post-failure analyses.

A body terminal 18 of a test PMOSFET 20 is connected to an integrated circuit pin 22 responsive to a power supply voltage V through a switch 24. A gate terminal 30 is switchably connected to a pin 31 (which is connected to ground when the integrated circuit 10 is operational) or to a pin 32 via a switch 34. As known by those skilled in the art, the switches 24 and 34 (and the other switches to be identified below) can be implemented according to one of several different circuit configurations, including NMOSFET and PMOSFET transistors controlled to operate as switches.

A source/drain terminal 40 of the test PMOSFET 20 is switchably connected to a pin 42 through a switch 44. A source/drain terminal 48 is switchably connected to a pin 50 through a switch 52.

A reference unstressed PMOSFET 60 comprises a gate terminal 62 switchably connected to the pin 32 through the switch 34, a source/drain terminal 64 switchably connected to the pin 42 through the switch 44 and a source/drain terminal 70 switchably connected to the pin 50 through the switch 52.

When the integrated circuit 10 is activated by application of the power supply voltage V to the active devices 11, the switch 24 is closed to connect the body terminal 18 to the supply voltage V and the switch 34 is configured to connect the gate terminal 30 to ground. With the gate terminal 30 and body terminal 18 connected across the supply voltage, the threshold voltage of the test PMOSFET 20 changes in response to temperature stresses (e.g., when the integrated circuit 10 and thus the PMOSFET 20 reach a temperature in excess of a design tolerance) and voltage stresses (i.e., when the integrated circuit 10 is subjected to a voltage in excess of a design tolerance). The threshold voltage shift is due primarily due to NBTI effects.

There are a number of known techniques for determining the threshold voltage of a MOSFET, from which the threshold voltage shift can be determined according to the present invention. See for example, Semiconductor Device and Material Characterization, by Dieter K. Schroder, 1998, pp. 242. To determine the post-operational threshold voltage and the threshold voltage shift of the PMOSFET test device 20, the integrated circuit 10 is powered down, the switch 24 is opened, the switch 34 is configured to connect the gate 30 of the test device 20 to the pin 32, the switch 44 is configured to connect the source/drain 40 to the pin 42 and the switch 52 is configured to connect the source/drain 48 to the pin 50.

A tester 80, connected to the pins 32, 42 and 50 is employed to determine the threshold voltage of the PMOSFET test device 20 and the PMOSFET reference device 60. According to one technique (referred to as gm (e.g., transconductance) maximum) the tester 80 suitably biases the sources/drains 40 and 48 (through the pins 42 and 50) to drive the PMOSFET into saturation. The gate voltage (through the pin 32) is ramped and the drain current determined during the ramping process to create a plot of Id versus Vg. A slope of the Id/Vg curve is the transconductance gm, or gm is the derivative of Id as a function of Vg. The maximum gm value is determined at a point of maximum slope on the Id versus Vg curve. From the point of maximum gm, the Id versus Vg curve is linearly extrapolated to the Vg axis, where the intersection of the line with the Vg axis indicates the threshold voltage.

According to another technique (referred to as the constant current method) a constant current is applied to the drain terminal while setting the drain and gate voltages to the same value. The voltage represents the threshold voltage for the supplied drain current.

To determine the threshold voltage of the PMOSFET reference device 60, the switch 24 is opened, the switch 34 is configured to connect the gate 62 of the reference device 60 to the pin 32, the switch 44 is configured to connect the source/drain 64 to the pin 42 and the switch 52 is configured to connect the source/drain 70 to the pin 50. The threshold voltage of the reference device 60 is determined by the tester 80, using any of the known threshold voltage determining techniques, including those described above.

A difference between the threshold voltage of the test PMOSFET 20 and the reference PMOSFET 60 represents the threshold voltage shift due to the voltage and temperature stresses experienced by the active devices 11 of the integrated circuit 10. Knowing the operating life and the threshold voltage shift of the test PMOSFET 20 of the integrated circuit 10 permits comparison with the previously-developed negative bias temperature instability NBTI) aging effect curves. The integrated history of power supply and temperature stresses experienced by the integrated circuit 10 can be deduced by comparing the measured threshold voltage shift with the expected threshold voltage shift for the operating life of the PMOSFET 20.

In another embodiment, it may be desirable to decrease the rate of aging of the test PMOSFET 20 to acquire information as to the timing of the experienced stresses. To accomplish this, a voltage divider comprising a resistor divider network, for example, is connected to the gate 30 of the PMOSFET test device 20 to lower the voltage between the gate terminal 30 and the body terminal 18 to a value below the full power supply voltage (e.g., 90% of the power supply voltage) and thereby modulate the rate of aging. It is known that the aging effects at the full power supply voltage tend to appreciably diminish after a given number of years of operating life, beyond which it may be difficult to observe aging effects as the aging process has essentially ended. The technique of reducing the power supply voltage supplied to the test PMOSFET 20 can be advantageously employed when it is desired to continue monitoring the aging effects beyond that number of years. Reducing the voltage between the gate and the body slows the aging rate and thus extends the period during which aging data can be collected.

In still another embodiment, the integrated circuit comprises a plurality of test PMOSFETS, each responsive to a different power supply voltage between its gate and body terminals, permitting collection of aging effect data during different time intervals. As the aging effects diminish for the PMOSFET operated at the full power supply voltage, continuing aging effects can be observed for the PMOSFETS operated at lower supply voltages.

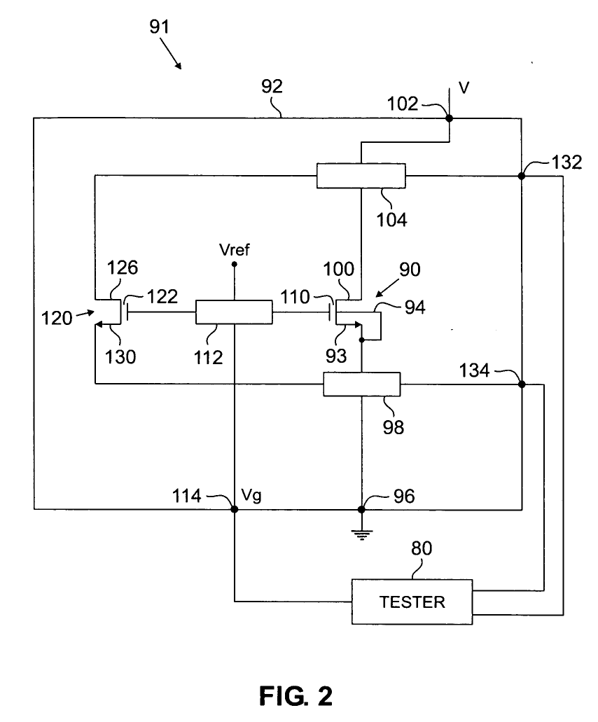

The integrated HCA stress can be determined using an NMOSFET test device 90, (see FIG. 2) fabricated in an integrated circuit 91 comprising a plurality of active devices indicated generally by a reference character 92. The NMOSFET test device 90 comprises a source/drain terminal 93 and a body terminal 94 connected to a pin 96 through a switch 98. When the integrated circuit 91 is operating the pin 96 is connected to ground. A source/drain terminal 100 is connected to a pin 102 through a switch 104. When the integrated circuit 91 is operating, the pin 102 is connected to a power supply voltage V. In a preferred embodiment a gate 110 is connected to a reference voltage VR of between about 0.4 and 0.5 volts through a switch 112. Preferably, the reference voltage is selected to cause maximal aging stress, from which the HCA stress experienced by the integrated circuit 91 can be determined. In one embodiment the reference voltage is about half of the power supply voltage V. As will be described further below, for determining a threshold voltage of the NMOSFET test device 90, the gate 110 is switchably connected to a pin 114 through the switch 112.

A reference NMOSFET 120 comprises a gate terminal 122 switchably connected to the pin 114 through the switch 112, a source/drain terminal 126 switchably connected to the pin 102 through the switch 104, and a source/drain terminal 130 switchably connected to the pin 96 through the switch 98.

When the integrated circuit 91 is activated by application of the power supply voltage V to the active devices 92, the switch 104 is configured to connect the source/drain terminal 100 to the supply voltage V, and the switch 98 is configured to connect the source/drain terminal 93 and the body terminal 94 to the pin 96, which is further connected to ground. The gate 110 is connected to the reference voltage by properly configuring the switch 112.

With the NMOSFET 120 connected as described, during operation of the integrated circuit 91 the threshold voltage of the NMOSFET 120 changes, primarily due to HCA effects, in response to a power supply voltage stress (i.e., a voltage in excess of a design tolerance) and/or a temperature stress (i.e., a temperature in excess of a design tolerance) experienced by the active devices 92 when the integrated circuit is powered.

To determine the threshold voltage shift caused by the operational stresses, the threshold voltage of the NMOSFET test device 90 is determined. The integrated circuit is powered down, the switch 104 is configured to connect the source/drain terminal 100 to a pin 132, the switch 112 is configured to connect the gate terminal 110 to the pin 114 and the switch 98 is configured to connect the source/drain terminal 93 and the body terminal 94 to a pin 134. The threshold voltage of the NMOSFET 90 can be measured by the tester 80 using the techniques described above for measuring the threshold voltage of the PMOSFET 20 or using other techniques known to those skilled in the art.

To determine the threshold voltage of the NMOSFET reference device 120, the switch 98 is configured to connect the source/drain terminal 130 to the pin 134, the switch 104 is configured to connect the source/drain terminal 126 to the pin 132 and the switch 112 is configured to connect the gate terminal 122 to the pin 114. The threshold voltage of the reference device 60 is determined by using the techniques described above or others known in the art.

A difference between the two measured threshold voltages of the NMOSFET test device 90 and the NMOSFET reference device 120 represents the threshold voltage shift due to the voltage and temperature stresses experienced by the active devices 92 of the integrated circuit 91, primarily due to HCA aging effects. Knowing the relative shift in the threshold voltage, the integrated HCA aging effects can be determined from standard processing technology lifetime curves that depict the expected threshold voltage shift due to HCA effects as a function of operating life. If the measured threshold voltage shift is greater that expected according to the HCA curves, then the integrated circuit 91 was likely exposed to voltage and/or temperature stresses during its operational life.

The integrated HCA and NBTI stress information provides valuable insight into the voltage and temperature stresses experienced by the integrated circuits 10 and 91, and additionally can be used to conduct more detailed failure analysis. For example, circuit level modeling of the integrated circuit can be conducted to determine whether the observed threshold voltage shift could have caused a chip failure.

Although the PMOSFET test and reference devices 20 and 60 are depicted as fabricated on a separate integrated circuit from the NMOSFET test and reference devices 90 and 120, for separately determining the NBTI and HCA aging effects, this is not a requirement of the present invention and was adopted merely for explanatory purposes. Typically, both the PMOSFET test and reference devices and the NMOSFET test and reference devices would be formed on the same integrated circuit for determining both the NBTI and HCA aging effects to which the device was exposed.

The teachings of the present invention can also be employed to identify “outlier” chips that may not be suitable for operational use. The performance characteristics of these chips may not be within a desired range and thus it is desired to identify these chips prior to shipment to a customer. Comparing the threshold voltage of the unstressed PMOSFET 60 or the unstressed NMOSFET 120 to the nominal threshold voltage distribution for the active devices 11 and the active devices 92, respectively, can determine whether an integrated circuit is an “outlier.”

The teachings of the present invention can also be used to more accurately evaluate ultimate device wear out, i.e., long-term device reliability. Correlations between integrated circuit failures and transistor degradation due to stresses that can be detected by threshold voltage level shifts as described above can be determined during high-level stress experiments prior to ramping up to full production of an integrated circuit. Such correlations can provide confidence that the integrated circuit will exhibit acceptable long-term reliability performance in the field.

According to another embodiment of the present invention, a system user receives a real-time warning of potential impending integrated circuit failures. The failure may be caused by unwanted fabrication process anomalies or unexpected stresses experienced during operation. In response to such a warning, the user can preemptively schedule removal and replacement of the integrated circuit or the hardware component into which it is embedded, thereby limiting potentially costly hardware failures. For example, failure of an integrated circuit within a disk drive will likely cause the drive to crash and the stored data to be lost. Significant productivity losses are incurred to replace the lost data. If the user had been forewarned of the failure, the disk drive could have been replaced before failure and the data transferred to the replacement disk drive.

The capability to provide such real time warnings can also be helpful to a user who may have received an outlier chip or who operates the integrated circuit in a harsh environment. Operation of an integrated circuit in a harsh environment, especially an environment near or exceeding the limits established for proper operation, exposes the chip to stresses that can cause accelerated aging and lead to premature chip failure. Outlier chips may have operational tolerances that are marginally close to an expected range of design tolerances and thus may be more likely to fail prematurely, especially when operated in a harsh environment

The embodiment providing an early warning of potential device failure allows integrated circuit designers and manufacturers to more aggressively design for reliability, despite today's smaller and denser integrated circuits, with the knowledge that users are less likely to suffer hardware system failures due to the ability to preemptively schedule system replacements in response to a warning. Thus the capability to provide a warning of an impending failure can enable lower cost implementations of an integrated circuit with a failure profile that is acceptable to the user. The failure warning ameliorates the erosion of the reliability margin.

The early warning component of the present invention provides important value to the user and is more beneficial than the current approach where the device temperature is monitored and a lower power mode enabled in response to an excessive temperature, thus negatively impacting the system user. The prior art systems do not track total operating time at high wear-out conditions or account for the possibility that certain devices may be more robust (i.e., less likely to fail under stress conditions) than others due to manufacturing variations. The current invention employs the concept of an overall lifetime budget and as the device approaches end-of-life, the user can take proactive steps to avoid unplanned downtime.

According to the present invention, data collected from the test and reference devices allows the user to determine allowable maximum operating conditions, taking the integrated circuit to the edge of reliability, while still providing expected performance. Current practice places a guard band around operating conditions to extend the chip's life, since life-shortening stress data is not available during operation.

In another embodiment, the chip modifies its behavior/performance in the field based on the actual aging as determined according to the present invention. That is, the integrated circuit initiates a change to its operating environment, for example by lowering the operating voltage, reducing the operating speed or activating a cooling device, such as a fan. This feature can prevent catastrophic failures in a case where the expected end-of-life is near. The chip can also report its expected remaining life to a host device to provide a user warning.

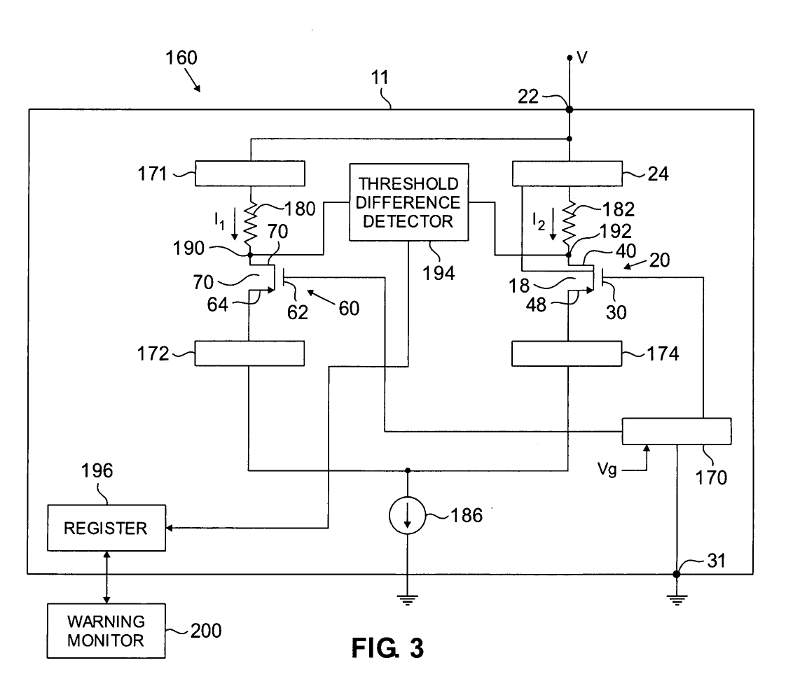

In one embodiment, a circuit for measuring the threshold voltage shift in real time is disposed on an integrated circuit 160 and comprises the PMOSFET test device 20 and the PMOSFET reference device 60 connected as a differential pair, as illustrated in FIG. 3. As described in conjunction with FIG. 1, the body terminal 18 of the PMOSFET test device 20 is connected to the power supply voltage V through the switch 24. Threshold voltage shifts in the PMOSFET test device 20 are caused by power supply and/or temperature stresses experienced by the active devices 11.

A switch 170 is configured to connect the gate terminal 30 of the PMOSFET test device 20 to ground to effect the threshold voltage shift during stress conditions. Switches 171 and 172 are in an open condition to isolate the PMOSFET reference device 60 from the effects of power supply and temperature stresses. A switch 174 is also opened to isolate the source/drain terminal 48 of the PMOSFET test device 20.

To perform a real time measurement of the threshold voltage shift, the switches 24 and 171 are closed to provide current flow I₁ through a resistor 180 and current flow I₂ through a resistor 182. A voltage V_{g} (supplied from an on-chip or an off-chip source) is supplied to the gate terminal 30 of the PMOSFET tests device 20 and the gate terminal 62 of the PMOSFET reference device 60 through the closed switch 170. The switches 172 and 174 are closed to connect the sources/drains terminals 64 and 48 to a current source 186.

With the same gate voltage applied to the gates 30 and 62, the currents I₁ and I₂ through the resistors 180 and 182 differ in response to the threshold voltage difference between their respective PMOSFETS. Thus the voltages at terminals 190 and 192 will also differ according to the threshold voltage difference. A threshold difference detector 194 determines the voltage difference and the threshold voltage shift or difference between the PMOSFET test device 20 and the PMOSFET reference device 60. The threshold difference detector 194 stores a value representing the measured threshold voltage shift in an on-chip memory element, such as a register 196. In another embodiment, the memory element for storing the value is located off-chip. To determine whether the active devices 11 have been subjected to power supply and/or temperature stresses, the stored shift is compared to the expected threshold voltage shift as a function of the device's operating life.

In one embodiment, the threshold difference detector 194 further comprises a comparator for comparing the threshold voltage shift to a reference value, in which embodiment the test result value stored in the register 196 indicates that the threshold shift reference has been exceeded. The reference is related to the expected threshold voltage shift for an unstressed PMOSFET or NMOSFET. Thus when the reference value is exceeded, the stored value indicates that the active devices 11 were apparently subjected to stress conditions and their life expectancy thereby reduced.

An integrated circuit fabricator can establish acceptable threshold shift references that are incorporated into the threshold difference detector 194 for comparison with the measured value. During device operation, the threshold voltage shift (which is a measure of device degradation) is periodically checked by configuring the switches as described above. The frequency of degradation testing is selected to be low enough so as not to wear out the PMOSFET reference device 60 and the PMOSFET test device 20, but frequent enough to detect a pending failure within the integrated circuit 160. In one embodiment, a single measurement of a threshold shift above a predetermined threshold voltage shift limit indicates a potential failure. In another embodiment, multiple samples of the PMOSFET reference device 60 and the PMOSFET test device 20 are required before a degraded status is indicated. In such an embodiment, the threshold difference detector 194 further comprises non-volatile storage elements for storing information relative to previous stress tests, In still another embodiment, compensation for the expected relaxation or recovery of the degradation effects when the PMOSFET reference device 60 and the PMOSFET test device 20 are powered down is included within the threshold voltage shift reference values.

In another embodiment, the register 196 stores information related to the measured threshold voltage shift and the expected threshold voltage shift for use by a warning monitor 200 to alert the user to an impending failure of the integrated circuit 160. In response to the warning, the user can replace the system, including the integrated circuit 160. Although an after-the-fact forensic failure analysis of the device may provide more detailed information as to the cause of the failure, this embodiment of the present invention provides an apparatus and method allowing the user to prevent a system failure caused by failure of an integrated circuit within the system.

In yet another embodiment, threshold voltage shifts indicative of successive degradation levels are provided. When the integrated circuit 160 is determined to have reached a first degradation level, such is indicated by contents of the register 196, system level software associated with the system hardware reads the register 196 and advises the end user that a first level hardware degradation has been identified. Successive degradation levels would be similarly indicated. Upon receiving a degradation warning, the user has the opportunity to schedule managed replacement of the hardware system before failure or data loss (in the case of a disk drive or storage system) occurs.

When a second, more severe degradation level is reached the integrated circuit 10 self-initiates a change to a less stressful operational mode (e.g., to reduce power supply and thermal stresses) in an effort to avoid failure of the hardware component in which the chip is embedded. As various degradation levels are experienced, software within the hardware system continues to manage operating conditions of the integrated circuit 160 and/or the hardware system to reduce or further limit additional degradation effects in an effort to extend the life of the integrated circuit 10 and limit the impact of its failure.

Because the invention is embedded in an operating integrated circuit (i.e., the integrated circuit 160), the apparatus is sensitive to manufacturing and environmental operating conditions from which the degradation can be predicted by determination of the threshold voltage shift. Thus the degradation effects and life expectancy predictions based thereon are more accurate than an estimated worst-case situation that is applied to all integrated circuits of the same type. The operational reliability estimate using the apparatus and method of the present invention is deterministically measured for each integrated circuit and its unique use pattern, manufacturing conditions and physical operating environment.

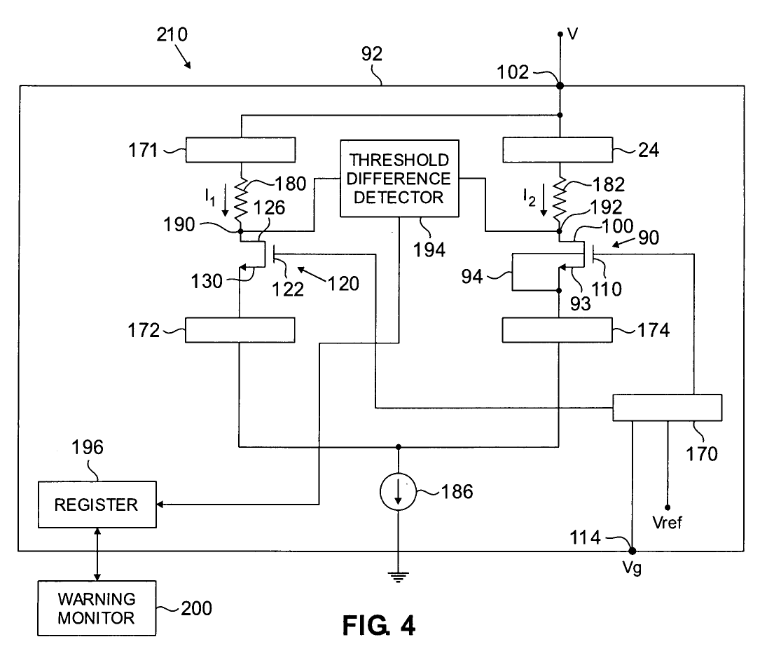

A circuit for measuring the threshold voltage shift of an NMOSFET disposed in an integrated circuit 210 comprises the NMOSFET test device 90 and the NMOSFET reference device 120 connected as a differential pair as illustrated in FIG. 4. The various terminals of the NMOSFET test device 90 and reference device 120 are connected as in FIG. 2.

As in the embodiment of FIG. 3, the threshold difference detector 194 determines the threshold voltage shift or the difference between the threshold voltage of the NMOSFET test device 90 and the threshold voltage of the NMOSFET reference device 120 as discussed in conjunction with the embodiment of FIG. 3. The difference between the two measured threshold voltages represents the threshold voltage shift due to the voltage and temperature stresses experienced by the active devices 92, primarily due to HCA aging effects, since these are more pronounced in NMOSFETS.

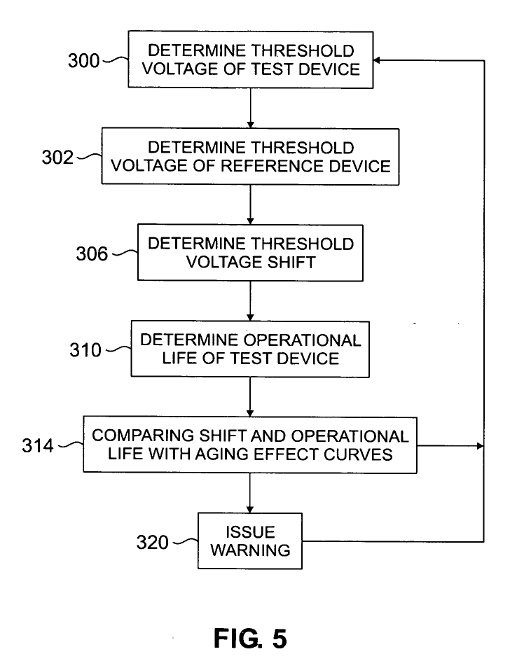

FIG. 5 depicts a flow chart for execution by a processor or controller, according to techniques known in the art, according to the teachings of the present invention. At a step 300 the threshold voltage of the PMOSFET or NMOSFET test device is determined, and the threshold voltage for the corresponding PMOSFET/NMOSFET reference device is determined at a step 302. The threshold voltage shift is determined at a step 306. At a step 310 the operational life of the PMOSFET/NMOSFET test device is determined. At a step 314 aging effect reference data is consulted to determine whether, based on the determined threshold voltage shift and the operational life of the PMOSFET/NMOSFET test device, the test device has a higher threshold voltage shift than expected for a device that has not been subjected to operating stresses associated with a power supply voltage and/or operating temperature in excess of a device specification. A warning is issued at a step 320 if operating stresses were determined at the step 314. To continually determine the existence of operational stresses, processing according to the flow chart returns to the step 300 from the steps 314 and 320.

While the invention has been described with reference to preferred embodiments, it will be understood by those skilled in the art that various changes may be made and equivalent elements may be substituted for the elements thereof without departing from the scope of the present invention. All examples and embodiment set forth herein are permissive rather than mandatory and illustrative rather than exhaustive. The scope of the present invention further includes any combination of the elements from the various embodiments set forth herein. In addition, modifications may be made to adapt a particular situation to the teachings of the present invention without departing from its essential scope. Therefore, it is intended that the invention not be limited to the particular embodiments disclosed, but that the invention will include all embodiments falling within the scope of the appended claims.

What is claimed is:

1. A method for determining exposure of an integrated circuit to operational stresses, wherein the integrated circuit comprises a test device and a reference device, and wherein the integrated circuit is connected to a power supply and to ground, the method comprising:
determining an operating parameter of the test device;
determining the operating parameter of the reference device; and
determining an operating parameter shift in response to the operating parameter of the test device and the operating parameter of the reference device.

2. The method of claim 1 wherein the test device comprises a MOSFET test device and the reference device comprises a MOSFET reference device, and wherein the operating parameter comprises a threshold voltage.

3. The method of claim 1 further comprising estimating a remaining life of the integrated circuit in response to the operating parameter shift.

4. The method of claim 1 further comprising issuing a user warning in response to the operating parameter shift.

5. The method of claim 1 further comprising modifying an operational parameter of the integrated circuit in response to the operating parameter shift.

6. The method of claim 5 wherein the operational parameter comprises a voltage supplied to the integrated circuit or an operating temperature of the integrated circuit.

7. The method of claim 1 wherein the test device is switchably connected between the power supply and ground such that the test device is responsive to one of a voltage supplied by the power supply or a fraction of the voltage supplied by the power supply, and wherein the reference device comprises an open circuit device.

8. The method of claim 1 further comprising:
determining an expected operating parameter shift as a function of operating life of the integrated circuit; and
comparing the operating parameter shift to the expected operating parameter shift.

9. The method of claim 8 further comprising determining that the integrated circuit has experienced operational stresses if the operating parameter shift is greater than the expected operating parameter shift.

10. The method of claim 8 further comprising estimating a remaining life of the integrated circuit in response to a relation between the operating parameter shift and the expected operating parameter shift.

11. The method of claim 1 wherein the test device comprises a MOSFET test device and the reference device comprises a MOSFET reference device, and wherein the operating parameter shift is related to at least one of hot carrier aging effects and negative bias temperature instability effects.

12. The method of claim 1 the test device comprising a MOSFET test device and the reference device comprising a MOSFET reference device, wherein the step of determining an operating parameter of the test device further comprises determining a threshold voltage of the MOSFET test device, and wherein the step of determining the operating parameter of the reference device further comprises determining the threshold voltage of the MOSFET reference device.

13. The method of claim 12 wherein the step of determining an operating parameter shift further comprises relating the threshold voltage of the MOSFET test device to the threshold voltage of the MOSFET reference device.

14. The method of claim 1 wherein the operational stresses are related to the operating parameter shift.

15. The method of claim 1 further comprising:
determining an operating life of the test device;
comparing the operating parameter shift to aging effect data indicating an expected operating parameter shift in response to the operating life of the test device; and
determining a relation between the operating parameter shift and the expected operating parameter shift; and
issuing a warning in response to a predetermined relation between the operating parameter shift and the expected operating parameter shift.

16. The method of claim 15 wherein the step of issuing a warning further comprises issuing the warning when the operating parameter shift exceeds the expected operating parameter shift.

17. The method of claim 15 wherein the test device comprises a MOSFET test device and the reference device comprises a MOSFET reference device, and wherein the aging effect data comprises at least one of hot carrier aging effect data or negative bias temperature instability aging effect data.

18. The method of claim 15 further comprising estimating a remaining integrated circuit life in response to the relation between the operating parameter shift and the expected operating parameter shift.

19. A method for determining operational stresses experienced by an integrated circuit comprising a MOSFET test device and a MOSFET reference device, wherein the integrated circuit including the MOSFET test device is switchably connected to a power supply and to ground, the method comprising;
determining an operating parameter of the MOSFET test device;
determining an operating parameter of the MOSFET reference device;
determining an operating parameter shift in response to the operating parameter of the MOSFET test device and the operating parameter of the MOSFET reference device,
determining an operating life of the MOSFET test device;
determining an expected operating parameter shift in response to the operating life of the MOSFET test device; and
comparing the operating parameter shift to the expected operating parameter shift.

20. The method of claim 19 wherein the extent to which the operating parameter shift exceeds the expected operating parameter shift indicates exposure of the integrated circuit to operating stresses.

21. The method of claim 19 wherein the operating parameter comprises a threshold voltage.

22. The method of claim 19 wherein the MOSFET test device comprises a plurality of MOSFETS, and wherein each one of the plurality of MOSFETS is responsive to a different power supply voltage for determining exposure of the integrated circuit to operating stresses during different time intervals of the operating life.

23. The method of claim 19 further comprising issuing a user warning in response to a relation between the operating parameter shift and the expected operating parameter shift.

24. The method of claim 19 further comprising modifying an operational parameter of the integrated circuit in response to a relation between the operating parameter shift and the expected operating parameter shift.

25. An apparatus for determining exposure of an integrated circuit to operational stresses, wherein the integrated circuit is connected to a power supply and to ground, the apparatus comprising:
a test device disposed in the integrated circuit;
a reference device disposed in the integrated circuit; and
a tester determining an operating parameter of the test device and of the reference device and determining an operating parameter shift in response to the operating parameter of the test device and the operating parameter of the reference device.

26. The apparatus of claim 25 wherein the operating parameter shift is related to exposure of the integrated circuit to operating stresses.

27. The apparatus of claim 25 wherein the test device comprises a test MOSFET and the reference device comprises a reference MOSFET.

28. The apparatus of claim 25 wherein the operating parameter comprises a threshold voltage of the test MOSFET and the reference MOSFET.

29. The apparatus of claim 25 further comprising a memory element for storing an operating parameter shift threshold, wherein the tester determines a relation between the operating parameter shift threshold and the operating parameter shift.

30. The apparatus of clam 25 further comprising a warning monitor issuing a warning in response to a relation between the operating parameter shift and an operating parameter shift threshold.

31. The apparatus of clam 25 further comprising a controller controlling operating characteristics of the integrated circuit in response to a relation between the operating parameter shift and an operating parameter shift control threshold.

32. The apparatus of claim 31 wherein the operating characteristics comprise at least one of a power supply voltage supplied to the integrated circuit, an operating speed of the integrated circuit or a temperature of the integrated circuit.

33. An apparatus for determining exposure of an integrated circuit to operating stresses, wherein during operation the integrated circuit is connected to a power supply and to ground, the apparatus comprising:
a test device formed in the integrated circuit from which is determined an operating parameter value;
a reference device formed in the integrated circuit from which is determined an operating parameter value; and
wherein the stress exposure of the integrated circuit is related to a difference between the operating parameter of the test device and the operating parameter of the reference device.

34. The apparatus of claim 33 wherein the operating parameter comprises a threshold voltage.

35. An apparatus for determining exposure of an integrated circuit to operational stresses, wherein the integrated circuit is connected to a power supply and to ground, the apparatus comprising:
a MOSFET test device formed in the integrated circuit, wherein the MOSFET test device comprises a first and a second drain/source region, a first gate region and a body region;
a MOSFET reference device formed in the integrated circuit, wherein the MOSFET reference device comprises a third and a fourth drain/source region and a second gate region;
a tester determining an operating parameter of the MOSFET test device and of the MOSFET reference device and determining an operating parameter shift in response thereto;
switching elements connecting one or more regions of the MOSFET test device to the power supply or to ground during operation of the integrated circuit;
switching elements connecting the first and the second drain/source regions, the first gate region and the body region to the tester to determine the operating parameter of the MOSFET test device; and
switching elements connecting the third and the fourth drain/source regions and the second gate region to the tester to determine the operating parameter of the MOSFET reference device.

36. The apparatus of claim 35 wherein the stress exposure of the integrated circuit is related to the operating parameter shift.

37. The apparatus of claim 35 wherein the operating parameter shift comprises a difference between the operating parameter of the MOSFET test device and the operating parameter of the MOSFET reference device.

38. The apparatus of claim 35 wherein the operating parameter comprises a threshold voltage.

39. The apparatus of claim 35 wherein the MOSFET test device comprises a PMOSFET test device and the switching elements connecting one or more regions of the MOSFET test device to the power supply or to ground during operation of the integrated circuit comprise a first switching element connecting the body region to the power supply voltage and a second switching element connecting the first gate region to ground.

40. The apparatus of claim 35 wherein the MOSFET test device comprises a NMOSFET test device and the switching elements connecting one or more regions of the MOSFET test device to the power supply or to ground during operation of the integrated circuit comprise a first switching element connecting the third source/drain region to the power supply, a second switching element connecting the first gate region to a reference voltage and a third switching element connecting the fourth source/drain region to ground.

41. An apparatus for determining a threshold voltage shift caused by operating stresses to which an integrated circuit has been exposed, the apparatus comprising:
a MOSFET test device disposed in the integrated circuit and connected to a power supply and ground;
a MOSFET reference device disposed in the integrated circuit; and
a threshold detector for determining a difference between the test device threshold voltage and the reference device threshold voltage.

42. The apparatus of claim 41 wherein the stresses to which the integrated circuit was exposed are related to the difference between the test device threshold voltage and the reference device threshold voltage.

43. The apparatus of clam 41 further comprising a controller for issuing a user warning in response to a relation between the test device threshold voltage and the reference device threshold voltage.

44. The apparatus of claim 41 wherein the controller controls operating characteristics of the integrated circuit.

45. The apparatus of claim 44 wherein the operating characteristics comprise at least one of a power supply voltage supplied to the integrated circuit, an operating speed of the integrated circuit or a temperature of the integrated circuit.
